(19) United States
(12) Patent Application Publication
(10) Pub. No.: US 2019/0259634 A1
(43) Pub. Date: Aug. 22, 2019

(54) PACKAGING STRUCTURE AND PACKAGING METHOD

(71) Applicant: China Wafer level CSP Co., Ltd., Suzhou, Jiangsu (CN)

(72) Inventors: Zhiqi Wang, Suzhou, Jiangsu (CN); Zhijie Shen, Suzhou, Jiangsu (CN); Zhiming Geng, Suzhou, Jiangsu (CN); Jian Zhang, Suzhou, Jiangsu (CN)

(73) Assignee: China Wafer level CSP Co., Ltd., Suzhou, Jiangsu (CN)

(21) Appl. No.: 16/314,833

(22) PCT Filed: Jun. 28, 2017
(86) PCT No.: PCT/CN2017/090508

§ 371 Date: Jan. 2, 2019

(30) Foreign Application Priority Data
Jul. 4, 2016 (CN) 201610516699.6
Jul. 4, 2016 (CN) 201620692372.X

(51) Int. Cl. H01L 21/56; H01L 23/31; H01L 23/522; H01L 23/492; H01L 23/00

(52) U.S. Cl. CPC H01L 21/565; H01L 23/31; H01L 2224/73204; H01L 23/4926; H01L 24/10; H01L 23/522

(57) ABSTRACT

A packaging structure and a packaging method are provided. The packaging structure includes a substrate, a circuit wiring layer arranged on the substrate, a conductive bump arranged on the circuit wiring layer, and a semiconductor chip flip-chip mounted over the substrate. A functional area and a pad surrounding the functional area are arranged on a first surface of the semiconductor chip facing the substrate, and the pad is electrically connected to the conductive bump. The packaging structure further includes a sealing layer arranged on the substrate and surrounding the semiconductor chip, and a blocking structure arranged on the substrate. The blocking structure surrounds the functional area to block a material of the sealing layer from overflowing into the functional area.

The present application claims priority to Chinese Patent Application No. 201610516699.6, titled “PACKAGING STRUCTURE AND PACKAGING METHOD”, filed on Jul. 4, 2016 and Chinese Patent Application No. 201620692372.X, titled “PACKAGING STRUCTURE”, filed on Jul. 4, 2016 with the Chinese Patent Office, which are incorporated herein by reference in their entireties.

### FIELD

The present disclosure relates to the technical field of semiconductor packaging technology, and in particular to a packaging structure and a packaging method.

### BACKGROUND

An image sensor is a sensor that senses external light and converts it into an electrical signal. After the image sensor chip is produced, a series of packaging processes are performed on the image sensor chip, to form a packaging structure as an image sensor or a part of an image sensor, so as to be used for various electronic devices such as digital cameras and digital video cameras.

In traditional packaging methods, the process of wire bonding is normally used for packaging. With the rapid development of integrated circuits, long leads make it difficult to achieve the desired product size. Therefore, the process of wafer level packaging (WLP) has gradually replaced wire bonding packaging as a common packaging method. The WLP technology has the following advantages. The entire wafer can be processed at the same time, leading to a high packaging efficiency. The whole wafer is tested before cutting, which reduces the testing process in the packaging process and reduces the testing cost. The packaging structure is light, small and thin.

However, the performance of the packaging structure formed by the conventional technology needs to be improved.

### SUMMARY

The problem to be solved by the present disclosure is how to provide a packaging structure and a packaging method to avoid contamination of a functional area and improve performance of the package structure.

In order to solve the above problems, the present disclosure provides a packaging structure, including a substrate, a circuit wiring layer arranged on the substrate, a conductive bump arranged on the circuit wiring layer, and a semiconductor chip flip-chip mounted over the substrate. A functional area and a pad surrounding the functional area are arranged on a first surface of the semiconductor chip facing the substrate, and the pad is electrically connected to the conductive bump. The packaging structure further includes a sealing layer arranged on the substrate, where the sealing layer surrounds the semiconductor chip, and a blocking structure arranged on the substrate, where the blocking structure surrounds the functional area to block a material of the sealing layer from overflowing into the functional area.

Optionally, a top of the circuit wiring layer is higher than a top of the substrate, or a top of the circuit wiring layer is flush with a top of the substrate, or a top of the circuit wiring layer is lower than a top of the substrate.

Optionally, the conductive bump encloses a designated area, and the blocking structure is in the designated area.

Optionally, the blocking structure is arranged between the conductive bump and the functional area. A top surface of the blocking structure is in contact with the first surface of the semiconductor chip, and a bottom surface of the blocking structure is in contact with the substrate.

Optionally, a top surface width dimension of the blocking structure is less than or equal to a bottom surface width dimension in a direction parallel to a top surface of the substrate.

Optionally, the conductive bump encloses a designated area. The blocking structure is outside the designated area and between the semiconductor chip and the substrate.

Optionally, an area where the semiconductor chip is projected onto the substrate is a projection area. The blocking structure is arranged in the projection area. A top surface of the blocking structure is in contact with the first surface of the semiconductor chip, and a bottom surface of the blocking structure is in contact with the substrate.

Optionally, the blocking structure includes: a first blocking structure and a second blocking structure which is attached to one side of the first blocking structure. An area where the semiconductor chip is projected onto the substrate is a projection area. The first blocking structure is arranged outside the projection area. The second blocking structure is arranged in the projection area. A top surface of the second blocking structure is in contact with the first surface of the semiconductor chip.

Optionally, a thickness of the second blocking structure on the substrate is a first thickness, and a distance between the first surface of the semiconductor chip and the substrate is equal to the first thickness.

Optionally, a thickness of the first blocking structure on the substrate is a second thickness, where the second thickness is greater than or equal to the first thickness.

Optionally, the sealing layer is further arranged on a top of the first blocking structure.

Optionally, an area where the semiconductor chip is projected onto the substrate is a projection area, the blocking structure is arranged outside the projection area, and a top of the blocking structure is higher than the first surface of the semiconductor chip.

Optionally, there is a gap between the blocking structure and a sidewall of the semiconductor chip in a direction parallel to a top surface of the substrate.

Optionally, a width dimension of the gap is 2 micrometers to 10 micrometers in the direction parallel to the top surface of the substrate.

Optionally, a distance between the top surface of the blocking structure and the first surface of the semiconductor chip is 2 micrometers to 10 micrometers in a direction perpendicular to the top surface of the substrate.

Optionally, the sealing layer is arranged on the top of the blocking structure.

Optionally, a shape of the blocking structure is a closed loop.

Optionally, the blocking structure is in contact with a sidewall of the conductive bump, and a material of the blocking structure is an insulating material.

Optionally, the blocking structure and the conductive bump are separated from each other, and a material of the blocking structure is an insulating material or a conductive material.

Optionally, the insulating material is a photosensitive paste.

Optionally, the blocking structure is a stacked structure, including: a bottom blocking layer in contact with the substrate and the circuit wiring layer, and a top blocking layer in contact with the first surface of the semiconductor chip. A material of the bottom blocking layer is an insulating material, and a material of the top blocking layer is a conductive material or an insulating material.

Optionally, the substrate includes a base, and the base is a light transmissive base or a PCB base. In a case that the base is the PCB base, a through hole extending through the PCB base is formed in the PCB base, and the functional area is arranged above the through hole. In a case that the base is the light transmissive base, a buffer layer is arranged on the light transmissive base, the circuit wiring layer is arranged on the buffer layer, an opening is formed on the buffer layer at a position corresponding to the functional area, and the light transmissive base is exposed from the opening.

Optionally, a material of the buffer layer is an organic polymer photoresist.

Optionally, the packaging structure further includes a solder bump on the substrate, where the solder bump is electrically connected to the circuit wiring layer, and the solder bump is arranged outside the semiconductor chip.

Optionally, the semiconductor chip is an image sensor chip, and the functional area is a photosensitive area.

The present disclosure further provides a packaging method, including: providing multiple individual semiconductor chips, where a first surface of each of the multiple the individual semiconductor chips has a functional area and a pad surrounding the functional area, providing a substrate, where the substrate includes flip-chip areas and a scribe line area between adjacent flip-chip areas; providing a circuit wiring layer on each of the flip-chip areas of the substrate; flip-chip mounting the semiconductor chip over the flip-chip area of the substrate, where the pad and the circuit wiring layer are electrically connected by a conductive bump; forming a sealing layer on the substrate, where the sealing layer surrounds each of the semiconductor chips; and cutting the substrate along the scribe line area after forming the sealing layer, to form multiple individual packaging structures. Before forming the sealing layer, the method further includes: forming a blocking structure on the substrate, where the blocking structure surrounds the functional area to block a material of the sealing layer from overflowing into the functional area.

Optionally, before flip-chip mounting the semiconductor chip over the substrate flip-chip area, the method further includes forming the conductive bump on the pad.

Optionally, before flip-chip mounting the semiconductor chip over the substrate flip-chip area, the method further includes forming the conductive bump on the circuit wiring layer.

Optionally, the forming a blocking structure on the substrate includes: forming a blocking film on the substrate; and exposing and developing the blocking film to form the blocking structure, or etching the blocking film to form the blocking structure.

Optionally, the flip-chip mounting the semiconductor chip over the flip-chip area of the substrate includes: placing the semiconductor chip on the flip-chip area of the substrate, where the pad is connected to the circuit wiring layer through the conductive bump; and performing a solder bonding process on the conductive bump, such that the pad is electrically connected to the circuit wiring layer through the conductive bump.

Optionally, after the semiconductor chip is flip-chip mounted over the flip-chip area of the substrate, the conductive bump encloses a designated area, and the blocking structure is in the designated area, or the blocking structure is outside the designated area and in a projection area of the semiconductor chip projected on the substrate. The blocking structure is formed before the semiconductor chip is flip-chip mounted over the flip-chip area of the substrate. A top surface of the blocking structure is in contact with the first surface of the semiconductor chip after the semiconductor chip is flip-chip mounted over the flip-chip area of the substrate.

Optionally, before performing the solder bonding process, a thickness of the conductive bump between the substrate and the first surface of the semiconductor chip is greater than or equal to a thickness of the blocking structure, and in the solder bonding process, the thickness of the conductive bump between the substrate and the first surface of the semiconductor chip is reduced such that the top surface of the blocking structure is in contact with the first surface of the semiconductor chip.

Optionally, the blocking structure includes: a first blocking structure and a second blocking structure which is attached to one side of the first blocking structure. After the semiconductor chip is flip-chip mounted over the flip-chip area of the substrate, an area where the semiconductor chip is projected onto the substrate is a projection area, the first blocking structure is arranged outside the projection area and the second blocking structure is arranged in the projection area. The blocking structure is formed before the semiconductor chip is flip-chip mounted over the flip-chip area of the substrate. A top surface of the second blocking structure is in contact with the first surface of the semiconductor chip after the semiconductor chip is flip-chip mounted over the flip-chip area of the substrate.

Optionally, in the solder bonding process, a thickness of the conductive bump between the substrate and the first surface of the semiconductor chip is reduced such that the top surface of the second blocking structure is in contact with the first surface of the semiconductor chip, and the first blocking structure covers a portion of a sidewall of the semiconductor chip.

Optionally, after the semiconductor chip is flip-chip mounted over the flip-chip area of the substrate, an area where the semiconductor chip is projected onto the substrate is a projection area, the blocking structure is arranged outside the projection area, and a top of the blocking structure is higher than the first surface of the semiconductor chip. The blocking structure is formed before the semiconductor chip is flip-chip mounted over the flip-chip area of the substrate, or the blocking structure is formed after the semiconductor chip is flip-chip mounted over the flip-chip area of the substrate.

Optionally, the method further includes forming a solder bump on the substrate, where the solder bump is electrically connected to the circuit wiring layer.

Optionally, the sealing layer is formed by a dispensing process or a molding process.

Compared with the conventional technology, the technical solution of the present application has the following advantages.

In the technical solution of the packaging structure provided in the present disclosure, a blocking structure is arranged on the substrate, and the blocking structure surrounds the functional area to block the material of the sealing layer from overflowing into the functional area, thereby avoiding the thereby avoiding contamination of the functional area and thus improving the performance of the packaging structure.

In an optional technical solution, a space enclosed by the blocking structure, the semiconductor chip, the substrate and the circuit wiring layer is a closed space, so that the blocking structure better blocks the material of the sealing layer from overflowing into the functional area, thereby further improving the performance of the packaging structure.

In an optional technical solution, in a direction parallel to the top surface of the substrate, the top surface width dimension of the blocking structure is less than or equal to the bottom surface width dimension, such that the area of the blocking structure in contact with the front surface of the semiconductor chip is small. Therefore, the area on the front side of the semiconductor chip required to be reserved for the blocking structure, so that the size of the semiconductor chip can be made smaller.

In an optional technical solution, in a case that the blocking structure is arranged outside the semiconductor chip, there is a gap between the blocking structure and the semiconductor chip in a direction parallel to the top surface of the substrate, and the gap has a width dimension of 2 micrometers to 10 micrometers. Since the width dimension of the gap is small, the material of the sealing layer is prevented from entering the functional area via the gap, so as to ensure that the blocking structure has a strong function of blocking the overflow of the sealing layer material.

### BRIEF DESCRIPTION OF THE DRAWINGS

FIGS. 1 and 2 are schematic structural diagrams of a packaging structure;

FIGS. 3 to 5 are schematic structural diagrams of a packaging structure according to an embodiment of the present disclosure;

FIGS. 6 to 9 are schematic diagrams of a packaging structure according to another embodiment of the present disclosure;

FIGS. 10 to 11 are schematic structural diagrams of a packaging structure according to another embodiment of the present disclosure;

FIGS. 12 to 15 are schematic structural diagrams showing the formation of a packaging structure according to an embodiment of the present disclosure;

FIGS. 16 to 19 are schematic structural diagrams showing the formation of a packaging structure according to another embodiment of the present disclosure; and

FIGS. 20 and 21 are schematic structural diagrams showing the formation of a packaging structure according to another embodiment of the present disclosure.

### DETAILED DESCRIPTION OF EMBODIMENTS

It is known from the background that the performance of the packaging structure formed by the conventional technology needs to be improved.

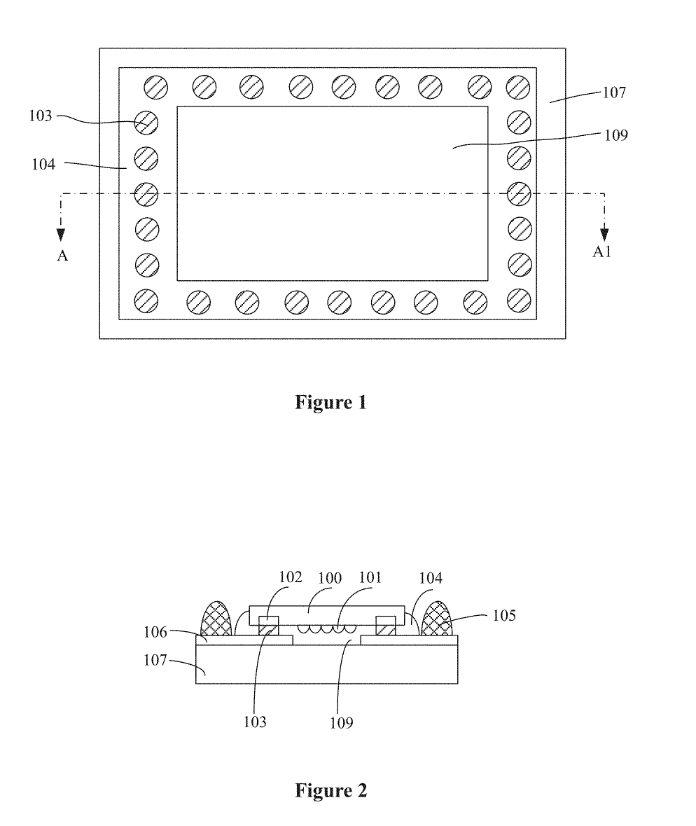

It should be noted that, the wording “above”, “below”, “left” and “right” are defined on the basis of the view shown in FIG. 1. It should be understood that the use of the wording does not limit the scope of protection claimed in the present disclosure.

Referring to FIGS. 1 and 2, FIG. 1 is a top view of the packaging structure, and FIG. 2 is a schematic cross-sectional view of the structure taken along line AA1 of FIG. 1.

It should be noted that, for convenience of illustration and description, the top view of the package structure is not fully illustrated in FIG. 1.

The packaging structure includes: a substrate 107 having a circuit wiring layer 106, where the circuit wiring layer 106 has an opening 109 exposing the substrate 107; a conductive bump 103 on the circuit wiring layer 106; an image sensor chip 100 flip-chip mounted over the substrate 107, where the front surface of the image sensor chip 100 has a photosensitive area 101 and a pad 102 surrounding the photosensitive area 101, and the pad 102 is electrically connected to the conductive bump 103; a dispensing layer 104 located on the circuit wiring layer 106 and covering the sidewall of the image sensor chip 100; and solder bump 105 located on the circuit wiring layer 106.

It is found that, due to the gap between the adjacent conductive bumps 103, the material of the dispensing layer 104 easily overflows into the photosensitive area 101 of the image sensor chip 100 through the gap during the process of forming the dispensing layer 104, and therefore contaminates the photosensitive area 101, which results in poor performance of the package structure, affecting the performance and yield of the packaging structure.

In order to solve the above problems, the present disclosure provides a packaging structure including a blocking structure which is on the substrate and surrounds the functional area. The blocking structure is adaptive to block the material of the sealing layer from overflowing into the functional area, so as to prevent the material of the sealing layer from overflowing into the functional area and contaminating the functional area, thereby improving the performance of the packaging structure.

The specific embodiments of the present disclosure are described in detail below with reference to the accompanying drawings.

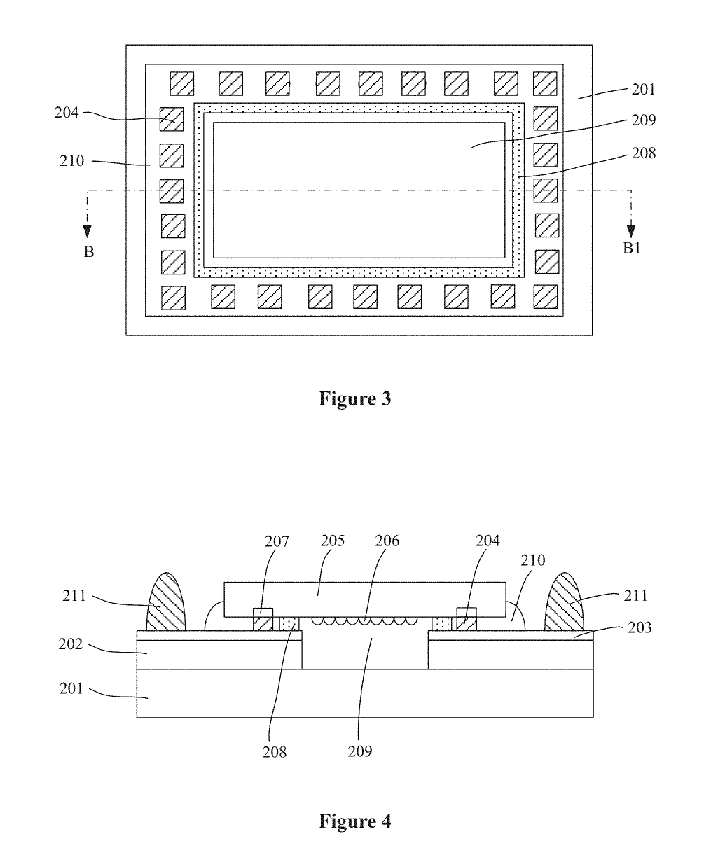

Referring to FIGS. 3 and 4, FIG. 3 is a schematic structural diagram of the packaging structure according to an embodiment of the present disclosure, and FIG. 4 is a schematic cross-sectional view of the structure taken along line BB1 of FIG. 3. The packaging structure includes:

a substrate;

a circuit wiring layer 203 arranged on the substrate;

a conductive bump 204 arranged on the circuit wiring layer 203;

a semiconductor chip 205 flip-chip mounted over the substrate, where a functional area 206 and a pad 207 surrounding the functional area 206 are arranged on a first surface of the semiconductor chip 205 facing the substrate, and the pad 207 is electrically connected to the conductive bump 204;

a sealing layer 210 arranged on the substrate, where the sealing layer 210 surrounds the semiconductor chip 205; and

a blocking structure 208 arranged on the substrate and the circuit wiring layer 203, where the blocking structure 208 surrounds the functional area 206 to block a material of the sealing layer 210 from overflowing into the functional area 206.

The packaging structure provided by this embodiment will be described in detail below with reference to the accompanying drawings.

In this embodiment, the substrate includes a base 201 and a buffer layer 202 on the base 201, and the buffer layer 202 has an opening 209 extending through the buffer layer 202.

The functional area 206 is above the opening 209. The functional area 206 can receive external light through the opening 209, where the base 201 is a light transmissive base or a PCB base. In this embodiment, the base 201 is a light transmissive substrate. In other embodiments, in a case that the base is a PCB base, a through hole is formed in the PCB base, and the functional area is above the through hole.

In other embodiments, the substrate may also be in a single layer structure including a base that is a light transmissive base or a PCB base.

The buffer layer 202 is advantageous for improving the adhesion between the circuit wiring layer 203 and the base 201, and thus improves the adhesion between the base 201 and the semiconductor chip 205. The material of the buffer layer 202 is an organic polymer photoresist, such as an epoxy resin and an acrylic resin.

In this embodiment, the circuit wiring layer 203 protrudes from the surface of the substrate. In other embodiments, the circuit wiring layer may also be arranged in the substrate, that is, the top of the circuit wiring layer is flush with the top of the substrate, or the top of the circuit wiring layer is lower than the top of the substrate.

In the embodiment, the circuit wiring layer 203 is arranged on the buffer layer 202, and the positions and number of the circuit wiring layers 203 correspond to the positions and number of the pads 207. Specifically, in a case that the functional area 206 has multiple pads 207 on four sides, the opening 209 has multiple separated circuit wiring layer 203 on four sides, each of the separated circuit wiring layer 203 is electrically connected to one of the pads 202, and the circuit wiring layer 203 is electrically connected to the pad 207 through the conductive bump 204. In other embodiments, in a case that the functional area has multiple pads on one side, the opening has the same number of separated circuit wiring layers on the side.

The material of the circuit wiring layer 203 is Cu, Al, W, Sn, Au or a Sn—Au alloy. The material of the conductive bump 204 is Au. Sn or a Sn alloy. The Sn alloy may be a tin-silver alloy, a tin-lead alloy, a tin-silver-copper alloy, a tin-silver-zinc alloy, or a tin-zinc alloy.

The conductive bump 204 is square or spherical. In this embodiment, the shape of the conductive bump 204 is square as an example.

The front surface of the semiconductor chip 205 has a functional area 206 and a pad 207 surrounding the functional area 206. The functional area 206 is formed with a functional unit and an associated circuit connected to the functional unit. In this embodiment, the semiconductor chip 205 is an image sensor chip. Correspondingly, the functional area 206 is a photosensitive area, and the functional area 206 receives external light and converts the received light into an electrical signal, and the electrical signal is transmitted to an external circuit through the pad 207 and the circuit wiring layer 203. In the present embodiment, an area in which the semiconductor chip 205 is projected onto the substrate is referred to as a projection area.

In this embodiment, in order to facilitate wiring, the functional area 206 is arranged at an intermediate position of the semiconductor chip 205, the pad 207 is arranged at an edge position of the semiconductor chip 205, and the pads 207 are arranged on four sides of the functional area 206 and are distributed in a rectangle. Each side is formed with multiple pads 207, and the number of the pads 207 depends on the type of the semiconductor chip 205. The pad 207 is connected to the circuit wiring layer 203, and the semiconductor chip 205 is connected to an external circuit through the circuit wiring layer 203.

It should be noted that, in other embodiments, the locations of the pads and functional areas may be flexibly determined according to actual needs. For example, in other embodiments, the pads may be arranged on one side, two sides, or three sides of the functional area.

The conductive bumps 204 have the following functions. First, the conductive bumps 204 realize the electrical connection between the circuit wiring layer 203 and the pads 207. Second, since the conductive bumps 204 are arranged between the pads 207 and the circuit wiring layer 203, the distance between the functional area 206 and the circuit wiring layer 203 in the direction perpendicular to the surface of the substrate 201 is large, so as to prevent the functional area 206 from touching the circuit wiring layer 203, thereby preventing the functional area 206 from being damaged. In this embodiment, the thickness of the conductive bump 204 is greater than the thickness of the photosensitive element in the functional area 206.

The packaging structure further includes: a solder bump 211 on the substrate, the solder bump 211 is electrically connected to the circuit wiring layer 203. In this embodiment, the solder bump 211 is arranged on the circuit wiring layer 203, and the solder bump 211 electrically connects the pads 207 to an external circuit, thereby allowing the semiconductor chip 205 to operate normally. The material of the solder bump 211 is gold, tin or tin alloy. In this embodiment, the top surface of the solder bump 211 is curved.

The sealing layer 210 has the following functions. First, the semiconductor chip 205 is in a closed space because of the sealing layer 210, preventing the semiconductor chip 205 from being ineffective under the influence of external environment, blocking moisture from the outside, and keeping electrically insulated from the outside. Second, the sealing layer 210 supports the semiconductor chip 205, to well fix the semiconductor chip 205 for circuit connection.

The material of the sealing layer 210 is a resin or a solder resist ink material, such as an epoxy resin and an acrylic resin.

In this embodiment, the sealing layer 210 is arranged not only on the sidewall of the semiconductor chip 205, but also on the substrate and the circuit wiring layer 203, and the top of the sealing layer 210 is lower than the bottom surface of the semiconductor chip 205, or, the top of the sealing layer 210 is flush with the bottom surface of the semiconductor chip 205. It should be noted that the bottom surface refers to the surface opposite to the front surface of the semiconductor chip 205.

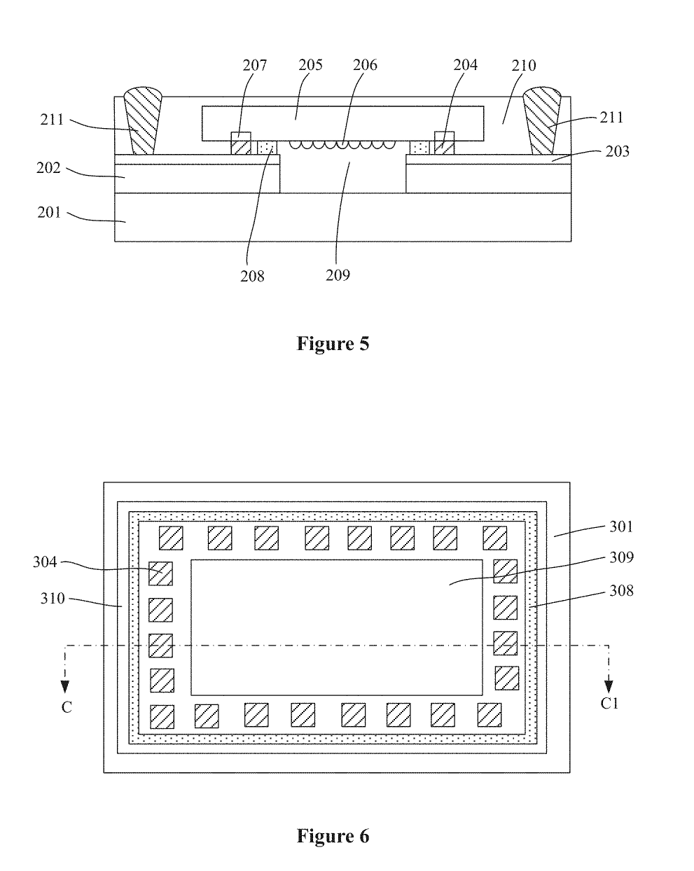

In this embodiment, the sealing layer 210 and the solder bump 211 are separated from each other. In other embodiments, the solder bump may also be arranged within the sealing layer and extend through the sealing layer, in other words, the solder bump is arranged on the substrate and outside the semiconductor chip. Specifically, referring to FIG. 5, the sealing layer 210 covers the substrate outside the projection area and covers the circuit wiring layer 203, and also covers the sidewall surface of the semiconductor chip 205 and the bottom surface. The solder bump 211 is arranged in the sealing layer 210 and extends through the sealing layer 210.

In this embodiment, the blocking structure 208 is arranged on the substrate and on the circuit wiring layer 203, and also surrounds the functional area 206. A space enclosed by the blocking structure 208, the semiconductor chip 205, the substrate and the circuit wiring layer 203 is a closed space, so that it is difficult for the material of the sealing layer 210 to enter the enclosed area, thereby effectively blocking the material of the sealing layer 210 from the functional area 206, and avoiding contamination of functional area 206.

Specifically, the conductive bump 204 on the substrate or circuit wiring layer 203 enclose a designated area, and the blocking structure 208 is in the designated area. In other words, the blocking structure 208 is in the aforementioned projection area, and is arranged between the conductive bump 204 and the functional area 206. The top surface of the blocking structure 208 is in contact with the front surface of the semiconductor chip 205, and the bottom surface of the blocking structure 208 is in contact with the circuit wiring layer 203 and the substrate.

In this embodiment, since the substrate includes the base 201 and the buffer layer 202, the blocking structure 208 is arranged on the circuit wiring layer 203 and the buffer layer 202. The top surface of the blocking structure 208 is in contact with the front surface of the semiconductor chip 205, and the bottom surface of the blocking structure 208 is in contact with the circuit wiring layer 203 and the buffer layer 202.

The thickness of the blocking structure 208 on the circuit wiring layer 203 is a first thickness, and a distance between a front surface of the semiconductor chip 205 and the circuit wiring layer 203 is equal to the first thickness. The thickness of the blocking structure 208 on the substrate is a second thickness, and a distance between the front surface of the semiconductor chip 205 and the substrate is equal to the second thickness. In this embodiment, the thickness of the blocking structure 208 on the buffer layer 202 is the second thickness, and the distance between the front surface of the semiconductor chip 205 and the buffer layer 202 is equal to the second thickness. It should be noted that the distance between the front surface of the semiconductor chip 205 and the circuit wiring layer 203 refers to the minimum distance between the front surface of the semiconductor chip 205 and the surface of the circuit wiring layer 203, and the distance between the front surface of the semiconductor chip 205 and the buffer layer 202 refers to the minimum distance between the front surface of the semiconductor chip 205 and the surface of the buffer layer 202.

In this embodiment, the top surface width dimension of the blocking structure 208 is equal to the bottom surface width dimension in a direction parallel to the substrate surface. In other embodiments, in order to reduce the space occupied by the blocking structure on the front surface of the semiconductor chip, the top surface width dimension of the blocking structure may also be smaller than the bottom surface width dimension, such that the blocking structure has a smaller area in contact with the front surface of the semiconductor chip, thereby saving the volume of the semiconductor chip.

The shape of the blocking structure 208 is a closed loop. The cross-sectional shape of the blocking structure 208 is a square ring shape, a circular ring shape, an elliptical ring shape or an irregular shape ring shape in a direction parallel to the surface of the substrate. In this embodiment, the cross-sectional shape of the blocking structure 208 is a square ring as an example.

In addition, it should be noted that the shape of the blocking structure 208 may also match the shape of the designated area surrounded by the conductive bumps 204. For example, if the shape of the area surrounded by the conductive bumps 204 is square, the cross-sectional shape of the conductive bump 208 is a square ring shape, and if the shape of the area surrounded by the conductive bump 204 is a circular shape, the cross-sectional shape of the conductive bump 208 is a circular ring shape. In this embodiment, the blocking structure 208 and the circuit wiring layer 203 are electrically insulated from each other in order to prevent the blocking structure 208 from adversely affecting the electrical connection performance of the packaging structure.

In this embodiment, the blocking structure 208 is a single layer structure, and the material of the blocking structure is an insulating material. In other embodiments, the blocking structure may also be a stacked structure. The blocking structure having a stacked structure may include: a bottom blocking layer in contact with the substrate and the circuit wiring layer, and a top blocking layer in contact with the front surface of the semiconductor chip, where the material of the bottom blocking layer is an insulating material, and the material of the top blocking layer is a conductive material or an insulating material. The conductive material includes copper, aluminum, tungsten or tin. The insulating material is a photosensitive adhesive, and the photosensitive adhesive includes an epoxy resin, an acrylic resin, a polyimide glue or a benzocyclobutene glue.

In addition, in the embodiment, the blocking structure 208 and the conductive bumps 204 are separated from each other, and there is a distance between the sidewall of the blocking structure 208 and the sidewall of the conductive bump 204, so that the blocking structure 208 does not affect the electrical connection properties of conductive bumps 204. The material of the blocking structure 208 may be an insulating material, and may also include conductive materials. In other embodiments, the sidewall of the blocking structure is in contact with the sidewall of the conductive bump. Since the shape of the blocking structure is a closed ring shape, in order to prevent the blocking structure from connecting the separated conductive bumps which results in an unnecessary electrical connection of the conductive bumps, the material of the blocking structure is an insulating material.

In the packaging structure provided by the embodiment, the blocking structure 208 is in a designated area surrounded by the conductive bumps 204, that is, the blocking structure 208 is between the conductive bumps 204 and the functional area 206, so that the blocking structure 208 provides protection to the functional area 206, preventing the material of the sealing layer 210 or other materials from entering the functional area 206 via the gap between the adjacent conductive bumps 204, thereby preventing the functional area 206 from being contaminated, and thereby improving the yield and electrical performance of the packaging structure.

In addition, the conductive bumps 204 correspond to the pads 207 on the semiconductor chip 205 in terms of locations. Since the blocking structures 208 are arranged between the conductive bumps 204 and the functional area 206, the blocking structure 208 is also between the pad 207 and the functional area 206. Therefore, there is no need to increase the distance between the pad 207 and the sidewall of the semiconductor chip 205 for placing the blocking structure 208, so that the semiconductor chip 205 has a small volume, which satisfies the development trend of miniaturization of the package structure.

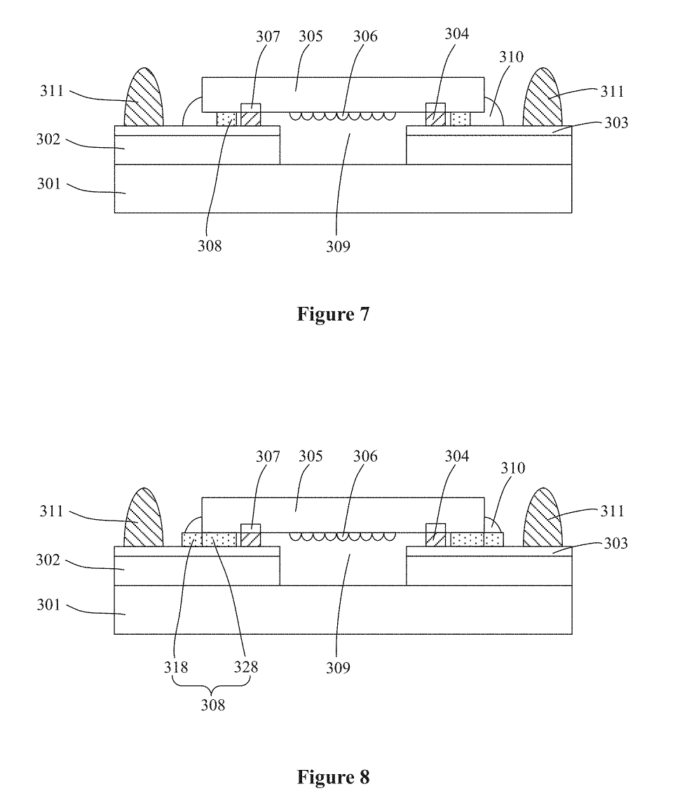

FIGS. 6 to 9 are schematic structural diagrams of the packaging structure according to another embodiment of the present disclosure. FIG. 6 is a schematic structural diagram of a top view of the packaging structure, and FIG. 7 is a schematic cross-sectional view of the structure taken along line CC 1 of FIG. 6. The packaging structure includes:

a substrate;

a circuit wiring layer 303 arranged on the substrate:

a conductive bump 304 arranged on the circuit wiring layer 303;

a semiconductor chip 305 flip-chip mounted over the substrate, where a functional area 306 and a pad 307 surrounding the functional area 306 are arranged on a first surface of the semiconductor chip 305 facing the substrate, and the pad 307 is electrically connected to the conductive bump 204;

a sealing layer 310 arranged on the substrate, where the sealing layer 310 surrounds the semiconductor chip 305; and

a blocking structure 308 arranged on the substrate and the circuit wiring layer 303, where the blocking structure 308 surrounds the functional area 306 to block a material of the sealing layer 310 from overflowing into the functional area 306.

The packaging structure provided by this embodiment will be described in detail below with reference to the accompanying drawings.

In this embodiment, taking the substrate including a base 301 and a buffer layer 302 on the base 301 as an example, the buffer layer 302 has an opening 309 extending through the buffer layer 302.

For a description of the base 301, the buffer layer 302, the opening 309, the circuit wiring layer 303, the conductive bump 304, the semiconductor chip 305, the functional area 306 and the pad 307, one may refer to the description of the previous embodiment, and details are not described herein again.

A space enclosed by the blocking structure 308, the semiconductor chip 305, the substrate and the circuit wiring layer 303 is a closed space. Different from the previous embodiment, in the embodiment, the conductive bumps 304 on the circuit wiring layer 303 enclose a designated area, and the blocking structure 308 is outside the designated area and between the semiconductor chip 305 and the circuit wiring layer 303. Accordingly, the sealing layer 310 is disposed not only on the buffer layer 302 and the sidewalls of the semiconductor chip 305, but also on the substrate and on the circuit wiring layer 303.

Referring to FIG. 7, in this embodiment, the area where the semiconductor chip 305 is projected on the substrate is a projection area, and the blocking structure 308 is arranged in the projection area. The top of the blocking structure 308 is in contact with the front surface of the semiconductor chip 305, and the bottom surface of the blocking structure 308 is in contact with the circuit wiring layer 303 and the substrate. Since the substrate includes the base 301 and the buffer layer 302, in the embodiment, the bottom surface of the blocking structure 308 is in contact with the circuit wiring layer 303 and the buffer layer 302.

For the material and structure of the blocking structure 308, one may refer to the description of the previous embodiment, which will not be repeated. In this embodiment, the blocking structure 308 and the conductive bump 304 are separated from each other. In other embodiments, the blocking structure may also be in contact with the sidewall of the conductive bump, and the material of the blocking structure is an insulating material.

The package structure further includes a solder bump 311 on the substrate, where the solder bump 311 is electrically connected to the circuit wiring layer 303. In this embodiment, the solder bump 311 is arranged on the circuit wiring layer 303, and the sealing layer 310 and the solder bump 311 are separated from each other. For the corresponding description, one may refer to the description of the previous embodiment. In other embodiments, the solder bumps 311 may also be arranged on the substrate and outside of the semiconductor chip.

In the packaging structure provided in this embodiment, the blocking structure 308 can not only block the sealing layer 310 material or other materials from entering the functional area 306 so as to avoid contamination to the functional area 306, but also protect the conductive bumps 304 from being contaminated by the material of the sealing layer 310 or other materials, and from damage to the conductive performance, thereby further improving the performance of the packaging structure.

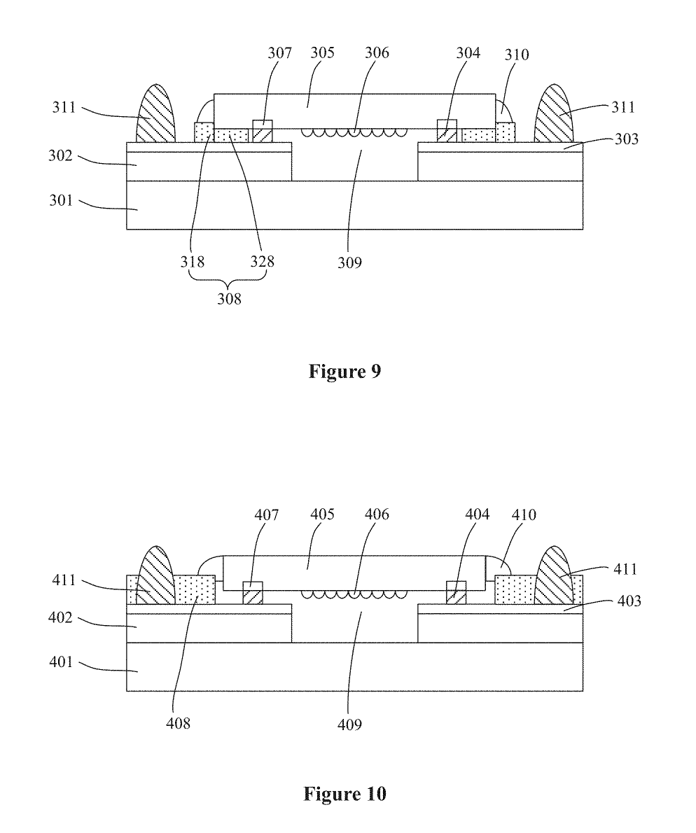

It should be noted that, in other embodiments, referring to FIG. 8 and FIG. 9, the conductive bumps 304 on the circuit wiring layer 303 enclose a designated area, and the blocking structure 308 is outside the designated area. In a case that the blocking structure 308 is also arranged between the semiconductor chip 305 and the circuit wiring layer 303, the blocking structure includes: a first blocking structure 318 and a second blocking structure 328 which is attached to one side of the first blocking structure 318. The area of the semiconductor chip 305 projected on the substrate is a projection area. The first blocking structure 318 is arranged outside the projection area, and the second blocking structure 328 is arranged in the projection area.

Moreover, a top surface of the second blocking structure 328 is in contact with a front surface of the semiconductor chip 305, and a bottom surface of the second blocking structure 328 is in contact with the circuit wiring layer 303 and the substrate. Specifically, the bottom surface of the second blocking structure 328 is in contact with the circuit wiring layer 303 and the buffer layer 302.

Since the space enclosed by the blocking structure 308, the semiconductor chip 305, the substrate and the circuit wiring layer 303 is a closed space, the thickness of the second blocking structure 328 on the substrate is a first thickness, and a distance between a front surface of the semiconductor chip 305 and the substrate is equal to the first thickness; a thickness of the second blocking structure 328 on the circuit wiring layer 303 is a third thickness, and the distance between the front surface of the semiconductor chip 305 and the circuit wiring layer 303 is equal to the third thickness. Specifically, in the embodiment, the thickness of the second blocking structure 328 on the buffer layer 302 is the first thickness, and the distance between the front surface of the semiconductor chip 305 and the buffer layer 302 is equal to the first thickness.

Accordingly, the sealing layer 310 is arranged not only on the sidewall of the semiconductor chip 305, but also on the first blocking structure 318. Alternatively, the sealing layer 310 is arranged not only on the top and sidewall of the first blocking structure 318 but also on the circuit wiring layer 303 and on the buffer layer 302.

Compared to a solution that does not have the first blocking structure, the first blocking structure 318 may function as a sealing layer. Therefore, the first blocking structure 318 occupies a portion of space of the sealing layer, thereby further reducing the possibility of contaminating the functional area 306 by the material of the sealing layer 310, and further preventing the material of the sealing layer 310 from contaminating the conductive bump 304.

Therefore, the performance of the packaging structure is further improved.

In an embodiment, referring to FIG. 8, the thickness of the first blocking structure 318 on the substrate is a second thickness, the thickness of the second blocking structure 328 on the substrate is a first thickness, and the second thickness is equal to the first thickness. That is, on the substrate, the top of the first blocking structure 318 is flush with the top of the second blocking structure 328, and also, on the circuit wiring layer 303, the top of the first blocking structure 318 is flush with the top of the second blocking structure 328. The sealing layer 319 is arranged on the top of the first blocking structure 318 and on the side of the semiconductor chip 305. In other embodiments, the sealing layer may be arranged not only on the top of the first blocking structure and the sidewall of the semiconductor chip, but also on the circuit wiring layer and the substrate.

In another embodiment, referring to FIG. 9, the thickness of the first blocking structure 318 on the substrate is a second thickness, and the thickness of the second blocking structure 328 on the substrate is a first thickness, and the second thickness is greater than the first thickness. That is, on the substrate, the top of the first blocking structure 318 is higher than the top of the second blocking structure 328, and also, on the circuit wiring layer 303, the top of the first blocking structure 318 is higher than the top of the second blocking structure 328 such that the first blocking structure 318 covers a portion of the sidewall of the semiconductor chip 305. The sealing layer 310 is arranged on the top of the first blocking structure 318 and on the sidewall of the semiconductor chip 305. In other embodiments, the sealing layer may also be arranged on the circuit wiring layer and on the substrate. Since the first blocking structure 318 covers a portion of the sidewall of the semiconductor chip 305, the ability of the first blocking structure 318 to block the material of the sealing layer 310 from overflowing into the functional region 306 is further improved.

In this embodiment, by disposing the blocking structure 308 outside the designated area surrounded by the conductive bumps 304, not only the functional area 306 is protected from contamination, but also there is no need to reserve a space between the conductive bump 304 and the functional area 306 for the blocking structure 308. Therefore, the distance between the conductive bump 304 and the functional area 306 can be reduced.

Furthermore, the distance between the blocking structure 308 and the functional area 306 is large, which prevents the blocking structure 308 from causing contamination or damage to the functional area 306, further improving the performance of the packaging structure.

In addition, the first blocking structure 318 arranged outside the projection area occupies a part of space of the sealing layer 310, further reducing the possibility of the material of the sealing layer 310 overflowing into the functional area 306. Moreover, both the first blocking structure 318 and the second blocking structure 328 can function to block the material of the sealing layer 310 from overflowing into the functional area 306. Therefore, the functional area 306 in the packaging structure provided by the embodiment can be better protected.

Another embodiment of the present disclosure further provides a packaging structure, and FIG. 10 and FIG. 11 are schematic structural diagrams of a packaging structure according to another embodiment of the present disclosure, where the packaging structure includes:

a substrate;

a circuit wiring layer 403 arranged on the substrate.

a conductive bump 404 arranged on the circuit wiring layer 403;

a semiconductor chip 405 flip-chip mounted over the substrate, where a functional area 406 and a pad 407 surrounding the functional area 406 are arranged on a first surface of the semiconductor chip 405 facing the substrate, and the pad 407 is electrically connected to the conductive bump 404;

a sealing layer 410 arranged on the substrate, where the sealing layer 410 surrounds the semiconductor chip 405, and

a blocking structure 408 arranged on the substrate and the circuit wiring layer 403, where the blocking structure 408 surrounds the functional area 406 to block a material of the sealing layer 410 from overflowing into the functional area 406.

The packaging structure provided by this embodiment will be described in detail below with reference to the accompanying drawings.

The substrate includes a base 401 and a buffer layer 402 on the base 401, and the buffer layer 402 has an opening 409 extending through the buffer layer 402.

Different from the foregoing embodiments, in this embodiment, the area of the semiconductor chip 405 projected on the substrate is a projection area, and the blocking structure 408 is arranged outside the projection area. Accordingly, the blocking structure 408 is arranged outside the semiconductor chip 405 and surrounds the semiconductor chip 405.

To ensure that the blocking structure 408 has the ability to block the material of the sealing layer 410 from overflowing into the functional area 306, the top of the blocking structure 408 is higher than the first surface of the semiconductor chip 405. Also, the distance between the top surface of the blocking structure 408 and the first surface of the semiconductor chip 405 should not be too small in a direction perpendicular to the surface of the substrate. If the distance is too small, the sealing layer 410 material is more likely to overflow into the functional area 406 via the void between the blocking structure 408 and the semiconductor chip 405, such that the ability of the blocking structure 408 to block the overflow of the sealing layer 410 material is poor.

Therefore, in the embodiment, the distance between the top surface of the blocking structure 408 and the first surface of the semiconductor chip 405 is 2 micrometers to 10 micrometers in the direction perpendicular to the surface of the substrate.

There is a gap between the blocking structure 408 and the sidewall of the semiconductor chip 405 in a direction parallel to the surface of the substrate. If the width dimension of the gap is too large, the material of the sealing layer 410 is more likely to overflow into the functional area 406 via the gap. Therefore, the gap has a width dimension of 2 micrometers to 10 micrometers in the direction parallel to the surface of the substrate.

It should be noted that the blocking structure 408 may also cover the sidewall of the semiconductor chip 405, that is, the gap may have a width dimension of 0.

The sealing layer 410 is arranged not only on the sidewall of the semiconductor chip 405, but also on the top of the blocking structure 408. In addition, the sealing layer 410 may also be arranged on the circuit wiring layer 403 and the buffer layer 402.

The packaging structure further includes a solder bump 411 on the substrate, where the solder bump 411 is electrically connected to the circuit wiring layer 403. In this embodiment, the solder bumps 411 are arranged on the circuit wiring layer 403.

In an embodiment, referring to FIG. 10, the blocking structure 408 covers the circuit wiring layer 403 and the buffer layer 402, and the solder bumps 411 are arranged in the blocking structure 408 and penetrate the blocking structure 408, the sealing layer 410 is arranged at a portion of the top of the blocking structure 408. It should be noted that, in other embodiments, the sealing layer may cover the entire top of the blocking structure, and the solder bump further penetrates the sealing layer.

In another embodiment, referring to FIG. 11, the blocking structure 408 is arranged on a portion of the circuit wiring layer 403 and on a portion of the substrate, the solder bumps 411 and the blocking structure 408 are separated from each other, and the sealing layer 410 is arranged on the top of the blocking structure 408. In other embodiments, the sealing layer may also cover the circuit wiring layer and the substrate, and the solder bump is arranged in the sealing layer and penetrates the sealing layer.

The shape of the blocking structure 408 is a closed shape, and the material of the blocking structure 408 is an insulating material or a conductive material. For a description of the materials and structures of the blocking structure 408, reference may be made to the corresponding description of the foregoing embodiments, and details are not described herein again.

In the package structure provided by the present disclosure, the top of the blocking structure is higher than the first surface of the semiconductor chip, so that the blocking structure can block the material of the sealing layer from overflowing into the functional area, thereby preventing the functional area from being contaminated. Thus the packaging structure has high performance, and the yield of the packaging structure is improved.

Furthermore, since the blocking structure 408 is arranged outside the projection area on which the semiconductor chip 405 is projected on the substrate, there is no need to reserve a spatial position in the semiconductor chip 405 for the blocking structure 408. Moreover, the blocking structure 408 has no influence on the flip-chip process performed on the substrate and the semiconductor chip 405, so the blocking structure 408 does not affect the spatial layout between the substrate and the semiconductor chip 405.

Correspondingly, a packaging method for forming the foregoing package structure is further provided in the present disclosure. The packaging method includes: providing multiple individual semiconductor chips, where a first surface of each of the multiple the individual semiconductor chips has a functional area and a pad surrounding the functional area; providing a substrate, where the substrate includes flip-chip areas and a scribe line area between adjacent flip-chip areas; providing multiple separated circuit wiring layers on the flip-chip area of the substrate; flip-chip mounting the semiconductor chip over the flip-chip area of the substrate, where the pad and the circuit wiring layer are electrically connected by a conductive bump; forming a sealing layer on the substrate, where the sealing layer surrounds the semiconductor chip; and cutting the substrate along the scribe line area after forming the sealing layer to form multiple individual packaging structures. Before forming the sealing layer, the method further comprises: forming a blocking structure on the substrate, where the blocking structure surrounds the functional area to block a material of the sealing layer from overflowing into the functional area. In the present disclosure, since a blocking structure is formed on the substrate before forming the sealing layer, the blocking structure surrounds the functional area and is adaptive to block a material of the sealing layer overflowing into the functional area. Therefore, in the process of forming the sealing layer, the blocking structure protects the functional area from the overflow of the sealing layer material into the functional area, so that the performance and yield of the formed packaging structures are improved.

The packaging method provided by the present disclosure will be described in detail below with reference to the accompanying drawings.

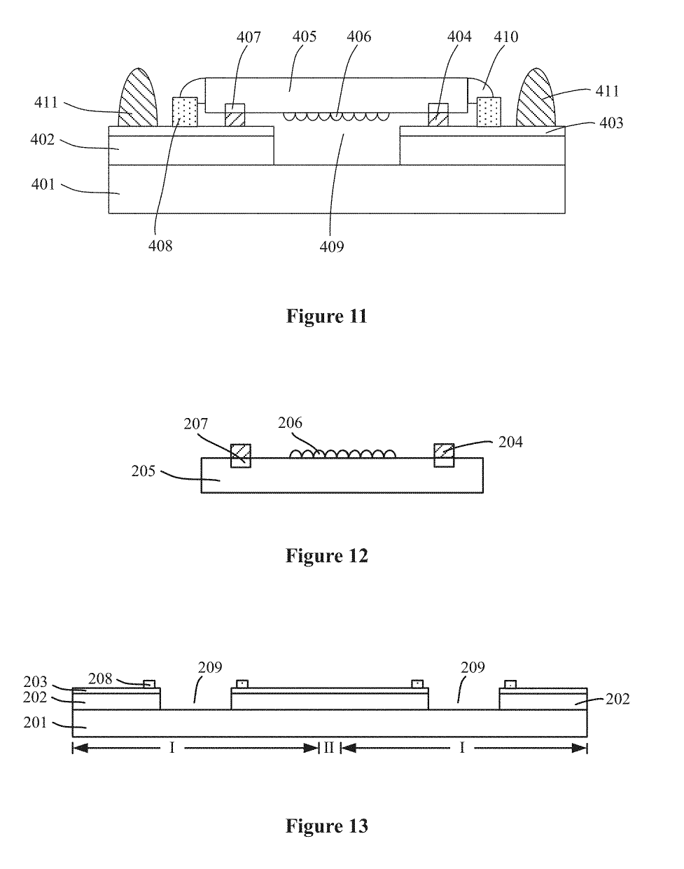

FIGS. 12 to 15 are schematic structural diagrams showing the formation of the packaging structure according to an embodiment of the present disclosure.

Referring to FIG. 12, multiple individual semiconductor chips 205 are provided.

The front surface of the semiconductor chip 205 has a functional area 206 and a pad 207 surrounding the functional area 206.

In this embodiment, the semiconductor chip 205 is an image sensing chip, and the functional area 206 is a photosensitive area. The semiconductor chip 205 is formed by cutting a wafer to be packaged. The wafer to be packaged includes multiple semiconductor chips 205 arranged in a matrix.

For a description of the functional area 206 and the pad 207, one may refer to the description in the foregoing packaging structure, and details are not described herein again.

Still referring to FIG. 12, the conductive bumps 204 are formed on the pads 207.

The positions and number of the conductive bumps 204 correspond to the positions and the number of the pads 207, and the shape of the conductive bumps 204 is square or sphere.

In this embodiment, the conductive bump 204 has a square shape, and the conductive bump 204 is formed by a screen printing process.

In other embodiments, the shape of the conductive bump may also be a spherical shape. The conductive bumps may be formed by a ball bonding process or a combination of a screen printing process and a reflow process.

It should be noted that, in other embodiments, the conductive bumps may not be formed on the pads, but formed on a circuit wiring layer subsequently provided on the substrate.

Referring to FIG. 13, a substrate is provided. The substrate includes flip-chip areas I and a scribe line area II between adjacent flip-chip areas I. The substrate flip-chip area I is provided with a circuit wiring layer 203.

The area of the flip-chip area and the scribe line area II can be determined according to actual packaging process requirements.

In the embodiment, the substrate includes a base 201 and a buffer layer 202 on the base 201. An opening 209 is formed in the buffer layer 202, which extends through the buffer layer 202. For the material of the base 201, reference may be made to the corresponding description in the foregoing packaging structure.

In the embodiment, the material of the buffer layer 202 is an organic polymer photoresist. The process of forming the buffer layer 202 includes: forming a buffer film on the base 201; and exposing and developing the buffer film to form the buffer layer 202 having the opening 209.

In the embodiment, the circuit wiring layer 203 protrudes from the surface of the substrate. The process of forming the circuit wiring layer 203 includes: forming a circuit layer on the buffer layer 202 and at the bottom and the sidewalls of the opening 209; patterning the circuit layer to remove the circuit layer on the bottom and sidewalls of the opening 209; and forming multiple separated circuit wiring layers 203 on the buffer layer 202.

In other embodiments, the circuit wiring layer may also be arranged in the substrate, that is, the top of the circuit wiring layer is flush with the top of the substrate, or the top of the circuit wiring layer is lower than the top of the substrate.

Still referring to FIG. 13, a blocking structure 208 is formed on the circuit wiring layer 203 and the substrate.

In the embodiment, the blocking structure 208 is formed on the circuit wiring layer 203 and the buffer layer 202.

The shape of the blocking structure 208 is a closed ring. The cross-sectional shape of the blocking structure 208 is a square ring shape, a circular ring shape, an elliptical ring shape or an irregular ring shape in a cross section parallel to the surface of the substrate.

In this embodiment, the semiconductor chip 205 (refer to FIG. 12) is flip-chip mounted over the flip-chip area I of the substrate subsequently, and the pad 207 is electrically connected to the circuit wiring layer 203 through the conductive bump 204. After the semiconductor chip 205 is flip-chip mounted over the flip-chip area I of the substrate, the conductive bump 204 encloses a designated area, and the blocking structure 208 is in the designated area.

The process of forming the blocking structure 208 includes: forming a blocking film on the substrate; and exposing and developing the blocking film to form the blocking structure, or etching the blocking film to form the blocking structure.

In this embodiment, in order to avoid unnecessary electrical connection between the circuit wiring layer 203 and the blocking structure 208, the blocking structure 208 is a single layer structure, and the material of the blocking structure 208 is an insulating material. In other embodiments, the blocking structure may be a stacked structure including a bottom blocking layer in contact with the circuit wiring layer and the substrate, and a top blocking layer in contact with the front surface of the semiconductor chip. The material of the bottom layer is an insulating material, the material of the top blocking layer is an insulating material or a conductive material, and the insulating material is a photosensitive adhesive.

In addition, in the embodiment, the blocking structure 208 and the conductive bump 204 are separated from each other. The material of the blocking structure 208 includes an insulating material, and the material of the blocking structure 208 may further include a conductive material. In other embodiments, in a case that the sidewall of the blocking structure is in contact with the sidewall of the conductive bump, the material of the barrier structure is an insulating material in order to ensure electrical insulation between adjacent conductive bumps.

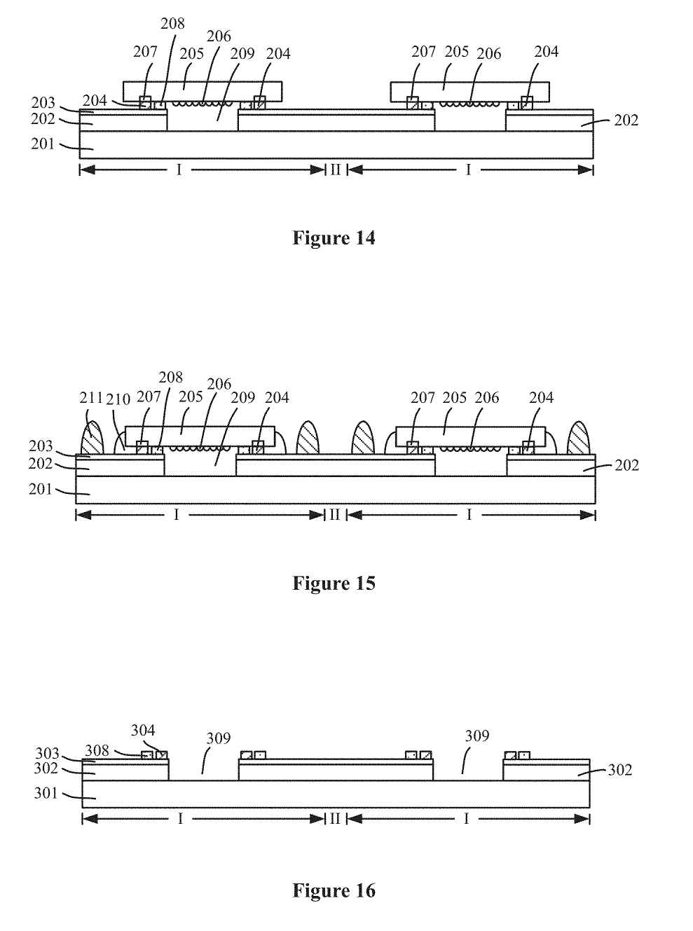

Referring to FIG. 14, the semiconductor chip 205 is flip-chip mounted over the flip-chip area I of the substrate, and the pad 207 and the circuit wiring layer 203 are electrically connected through the conductive bumps 204.

Specifically, each pad 207 corresponds to a separated conductive bump 204. In other words, each of the pads 207 corresponds to a separated circuit wiring layer 203.

The process of flip-chip mounting the semiconductor chip 205 over the flip-chip area I of the substrate includes: placing the semiconductor chip 205 on the flip-chip area I of the substrate, where the pad 207 is connected to the circuit wiring layer 203 through the conductive bump 204; and performing a solder bonding process on the conductive bump 204, such that the pad 207 is electrically connected to the circuit wiring layer 203 through the conductive bump 204.

The solder bonding process is performed by an eutectic bonding process, an ultrasonic thermocompression bonding process, or a thermocompression welding process.

Before the solder bonding process, the thickness of the conductive bump 204 between the substrate and the front surface of the semiconductor chip 205 is greater than or equal to the thickness of the blocking structure 208. During the solder bonding process, the thickness of the conductive bumps 204 between the substrate and the front surface of the semiconductor chip 205 is reduced, such that the top surface of the blocking structure 208 is in contact with the front surface of the semiconductor chip 205.

After the semiconductor chip 205 is flip-chip mounted over the flip-chip area I of the substrate, the conductive bump 204 encloses a designated area, and the blocking structure 208 is in the designated area. After the solder bonding process is performed, a space enclosed by the blocking structure 208, the semiconductor chip 205, the circuit wiring layer 203 and the substrate is a closed space, thereby preventing the material of the subsequently formed sealing layer from overflowing into the functional area 206.

In addition, it should be noted that, after the semiconductor chip 205 is placed on the substrate and before the solder bonding process is performed, the difference between the thickness of the conductive bump 204 between the substrate and the semiconductor chip 205 and the thickness of the blocking structure 208 should not be too large. If the difference is too large, after the solder bonding process, an aperture may be formed between the blocking structure 208 and the front surface of the semiconductor chip 205, and a subsequently formed sealing layer may diffuse into the functional region 206 via the aperture.

Referring to FIG. 15, a sealing layer 210 is formed on the substrate, and the sealing layer 210 surrounds the semiconductor chip 205.

The sealing layer 210 is used to seal the semiconductor chip 205 to prevent the external environment from adversely affecting the semiconductor chip. In this embodiment, the sealing layer 210 is also arranged on part of the circuit wiring layer 203. In other embodiments, the sealing layer may also cover the back surface of the semiconductor chip. In addition, the sealing layer may also cover the entire substrate surface exposed by the semiconductor chip.

In this embodiment, the sealing layer 210 is formed by a dispensing process. In other embodiments, the sealing layer may also be formed by a molding process, where the molding process is a transfer molding process or an injection molding process.

In the process of forming the sealing layer 210, the blocking structure 210 is adaptive to block the material of the sealing layer 210 from overflowing into the functional area 206, that is, preventing the material of the sealing layer 210 from entering the functional area 206 via a gap between adjacent conductive bumps 204, and thus preventing functional area 206 from being contaminated. Therefore, the performance and yield of the packaging structures are improved.

Still referring to FIG. 15, the method also includes: forming the solder bumps 211 on the substrate, where the solder bumps 211 are electrically connected to the circuit wiring layer 203.

In the embodiment, the solder bump 211 is formed on the circuit wiring layer 203. The solder bump 211 electrically connects the pad 207 to an external circuit, thereby causing the semiconductor chip 205 to work normally.

In this embodiment, the solder bump 211 and the sealing layer 210 are separated from each other. In other embodiments, the solder bump may also be arranged in the sealing layer and penetrate the sealing layer.

Referring to FIG. 15 and FIG. 4, the subsequent process further includes: cutting the substrate along the scribe line area II to form multiple individual packaging structures as shown in FIG. 4.

Another embodiment of a packaging method is further provided in the present disclosure. FIGS. 16 to 19 are schematic structural diagrams showing the formation of the packaging structure according to another embodiment of the present disclosure.

The difference from the previous embodiment is that, in the embodiment, the conductive bumps on the circuit wiring layer enclose the designated area, the formed blocking structure is arranged outside the designated area and surrounds the conductive bumps, and the blocking structure is also arranged between the semiconductor chip and the circuit wiring layer.

Referring to FIG. 16, a substrate is provided. The substrate includes flip-chip areas I and a scribe line area II between adjacent flip-chip areas. The circuit wiring layer 303 is provided on the substrate. The conductive bumps 304 is formed on the circuit wiring layer 303, and the blocking structure 308 is formed on the substrate, where the blocking structure 308 surrounds the conductive bump 304.

The substrate includes a base 301 and a buffer layer 302 on the base 301, where the buffer layer 302 has an opening 309 extending through the buffer layer 302.

In this embodiment, the conductive bumps 304 on the circuit wiring layer 303 enclose a designated area, and the blocking structure 308 is formed outside the designated area. For the material and structure of the blocking structure 308, reference may be made to the corresponding description of the foregoing embodiment, and details are not described herein again.

It should be noted that, in other embodiments, the conductive bump may be formed after the blocking structure is formed.

Furthermore, the conductive bump may be not formed on the circuit wiring layer, but formed on the pad of the subsequently provided semiconductor chip.

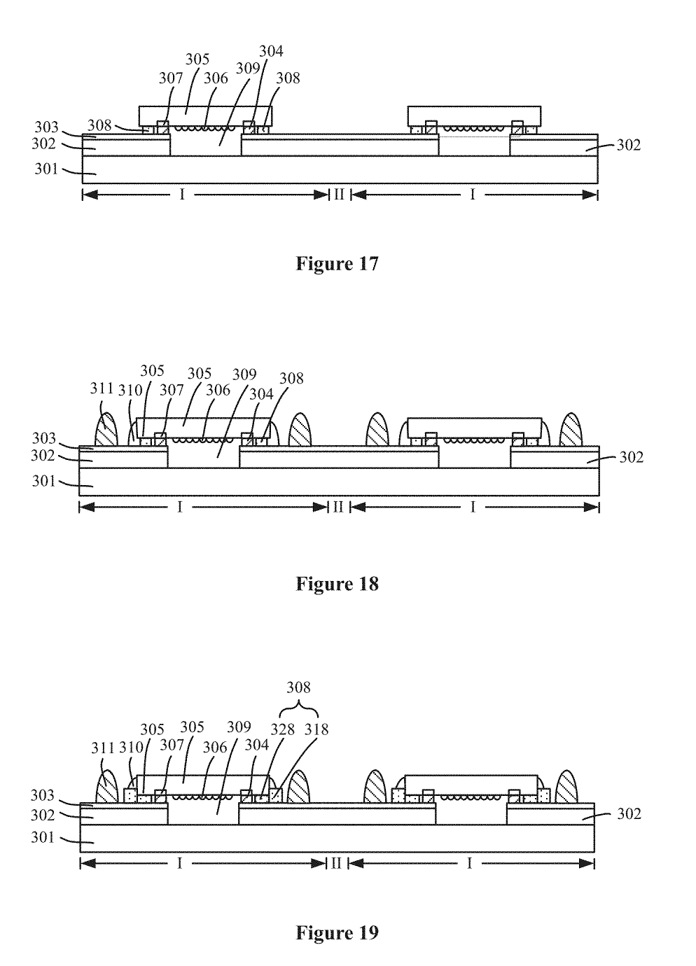

Referring to FIG. 17, the semiconductor chip 305 is provided, where the front surface of the semiconductor chip 305 has a functional area 306 and a pad 307 surrounding the functional area 306. The semiconductor chip 305 is flip-chip mounted over the flip-chip area I of the substrate, where the pad 307 and the circuit wiring layer 303 are electrically connected through the conductive bumps 304.

The step of flip-chip mounting the semiconductor chip 305 over the flip-chip area I of the substrate includes: placing the semiconductor chip 305 on the flip-chip area I of the substrate, where the pad 307 is connected to the circuit wiring layer 303 through the conductive bump 304; and performing the solder bonding processing on the conductive bump 304 such that the pad 307 is electrically connected to the circuit wiring layer 303 through the conductive bump 304.

For the solder bonding process, one may refer to the corresponding description of the previous embodiment, and details are not described herein again. In this embodiment, before the solder bonding process, the thickness of the conductive bump 304 between the substrate and the front surface of the semiconductor chip 305 is greater than or equal to the thickness of the blocking structure 306. During the solder bonding process, the thickness of the conductive bumps 304 between the substrate and the front surface of the semiconductor chip 305 is reduced, such that the top surface of the blocking structure 308 is in contact with the front surface of the semiconductor chip 305.

Therefore, in the embodiment, after the semiconductor chip 305 is flip-chip mounted over the flip-chip area I of the substrate, the top surface of the blocking structure 308 is in contact with the front surface of the semiconductor chip 305, and thus a space enclosed by the blocking structure 308, the semiconductor chip 305, the substrate and the circuit wiring layer 303 is a closed space. In this embodiment, after the semiconductor chip 305 is flip-chip mounted over the flip-chip area I of the substrate, the conductive bumps 304 enclose a designated area, and the blocking structure 308 is outside the designated area, and in the projection area of the semiconductor chip 305 projected on the substrate.

In other embodiments, with reference to FIG. 19, the blocking structure 308 is arranged outside the designated area. The blocking structure 308 includes: a first blocking structure 318 and a second blocking structure 328 which is attached to one side of the first blocking structure 318. After the semiconductor chip 305 is flip-chip mounted over the flip-chip area I of the substrate, the area where the semiconductor chip 305 is projected on the substrate is a projection area, the first blocking structure 318 is outside the projection area, and the second blocking structure 328 is in the projection area. Correspondingly, the blocking structure 308 is formed before the semiconductor chip 305 is flip-chip mounted over the flip-chip area I of the substrate. After the semiconductor chip 305 is flip-chip mounted over the flip-chip area I of the substrate, the top surface of the second blocking structure 328 is in contact with the front surface of the semiconductor chip 305. During the solder bonding process, the thickness of the conductive bumps 304 between the substrate and the front surface of the semiconductor chip 305 is reduced, such that the top surface of the second blocking structure 328 is in contact with the front surface of the semiconductor chip 305.

Furthermore, in a case that the thickness of the first blocking structure 318 is equal to the thickness of the second blocking structure 328, the top of the first blocking structure 318 is flush with the front surface of the semiconductor chip 305. In a case that the thickness of the second blocking structure 328 is greater than the thickness of the first blocking structure 318, the first blocking structure 318 also covers a portion of the sidewall of the semiconductor chip 305 after the solder bonding process.

Referring to FIG. 18, the sealing layer 310 is formed on the substrate, where the sealing layer 310 surrounds the semiconductor chip 30. The solder bump 311 is formed on the substrate, where the solder bump 311 is electrically connected to the circuit wiring layer 303.

In the embodiment, the sealing layer 310 is further arranged on the circuit wiring layer 303 and a part of a side surface of the semiconductor chip 305, and the sealing layer 310 is formed by a dispensing process or a molding process.

In this embodiment, the solder bump 311 and the sealing layer 310 are separated from each other, and the solder bump 311 is arranged on the substrate and outside the semiconductor chip 305. In other embodiments, the solder bump may also be arranged in the sealing layer and penetrate the sealing layer.

During the process of forming the sealing layer 310, the blocking structure 308 blocks the material of the sealing layer 310, so that the material of the sealing layer 310 cannot overflow into the functional area 306, thereby avoiding contamination of the functional area 306. In addition, the blocking structure 308 can also protect the conductive bumps 304 by preventing the sealing layer 310 material from contaminating the conductive bumps 304 or interfering with the conductive properties of the conductive bumps 304.

In other embodiments, referring to FIG. 19, the blocking structure 308 includes a first blocking structure 318 and a second blocking structure 328 which is attached to the first blocking structure 318. The top surface of the second blocking structure 328 is in contact with the front surface of the semiconductor chip 305, and the top of the first blocking structure 318 is flush with the front surface of the semiconductor chip 305. Alternatively, the top of the first blocking structure 318 is higher than the front surface of the semiconductor chip 305, and the first blocking structure 318 further covers the sidewall of the semiconductor chip 305. Correspondingly, the sealing layer 310 is formed on the top of the first blocking structure 318, and the sealing layer 310 may also be arranged on the circuit wiring layer. The first blocking structure 318 can function as the sealing layer 310 such that the first blocking structure 318 occupies a space originally for the sealing layer 310, thereby further reducing the risk of the material of the sealing layer 310 overflowing into the functional area 306.

Referring to FIGS. 18 and 7, and FIGS. 19 and 9, the subsequent process includes: cutting the substrate along the scribe line area II to form multiple individual packaging structures as shown in FIGS. 7 and 9.

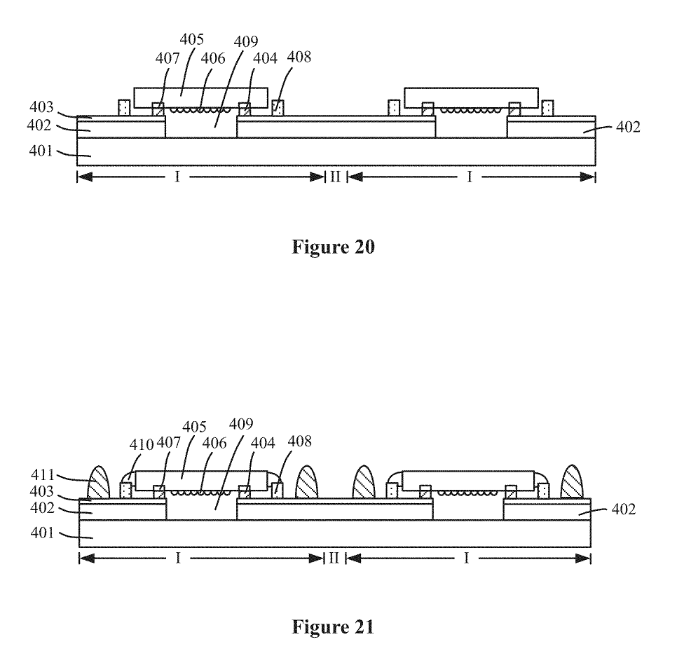

Another embodiment of the present disclosure further provides a packaging method. FIGS. 20 and 21 are schematic structural diagrams showing the formation of the packaging structure according to another embodiment of the present disclosure.

The difference from the foregoing embodiment is that, in the embodiment, the area where the semiconductor chip is projected on the substrate is a projection area, the formed blocking structure is arranged outside the projection area, and the top of the blocking structure is higher than the front surface of the semiconductor chip.

Referring to FIG. 20, the substrate is provided, where the substrate includes flip-chip areas I and a scribe line area II between adjacent flip-chip areas I, and the flip-chip area I of the substrate has a circuit wiring layer 403. The conductive bump 404 is formed on the circuit wiring layer 403. The blocking structure 408 is formed on the circuit wiring layer 403 and on the substrate. The semiconductor chip 405 is provided, where the front surface of the semiconductor chip 405 has a functional area 406 and a pad 407 surrounding the functional area 406. The semiconductor chip 405 is flip-chip mounted over the flip-chip area I of the substrate, where the pad 407 and the circuit wiring layer 403 are electrically connected by the conductive bump 404.

In this embodiment, the substrate includes a base 401 and a buffer layer 402 on the base 401, where the opening 409 penetrating the buffer layer 402 is formed in the buffer layer 420.

One may refer to the foregoing description for the material and structure of the blocking structure 408, and details are not described herein again.

In this embodiment, after the semiconductor chip 405 is flip-chip mounted over the flip-chip area I of the substrate, the area where the semiconductor chip 405 is projected on the substrate is a projection area, the blocking structure 408 is outside the projection area, and the top of the blocking structure 408 is higher than the front surface of the semiconductor chip 405.

In this embodiment, there is a gap between the blocking structure 408 and the sidewall of the semiconductor chip 405. Since the sealing layer covering the sidewall of the semiconductor chip 405 is formed on the blocking structure 408 subsequently, if the width dimension of the gap is too large, the material of the sealing layer can easily overflow into the functional area 406 via the gap. Therefore, in this embodiment, the width of the gap is 2 micrometers to 10 micrometers in a direction parallel to the surface of the substrate.

In this embodiment, the top of the blocking structure 408 is higher than the front surface of the semiconductor chip 405. In order to ensure that the blocking structure 408 has a strong ability to block the overflow of the material of the sealing layer, the distance between the top of the blocking structure 408 and the front surface of the semiconductor chip 405 should not be too small. Therefore, in the embodiment, the distance between the top surface of the blocking structure 406 and the front surface of the semiconductor chip 405 is 2 micrometers to 10 micrometers in a direction perpendicular to the surface of the substrate.

It should be noted that, in other embodiments, the gap width dimension between the blocking structure and the sidewall of the semiconductor chip may also be 0, that is, the blocking structure covers the sidewall of the semiconductor chip.

In addition, in the embodiment, the blocking structure 408 is formed before the semiconductor chip 405 is flip-chip mounted over the flip-chip area I of the substrate, which avoids unnecessary damage to semiconductor chip 405 in the process of forming the blocking structure 408. In other embodiments, the blocking structure may also be formed after flip-chip mounting the semiconductor chip over the flip-chip area of the substrate.

For the process of forming the blocking structure 408, reference may be made to the description of the foregoing embodiments, and details are not described herein again. The area of the blocking structure 408 covering the circuit wiring layer 403 can be flexibly adjusted according to requirements.

Referring to FIG. 21, the sealing layer 410 is formed on the substrate, and the sealing layer 410 surrounds the semiconductor chip 405. The solder bump 411 is formed on the substrate, and the solder bump 411 is electrically connected to the circuit wiring layer 403.

In the embodiment, the sealing layer 410 is further arranged on the top of the blocking structure 408. During the process of forming the sealing layer 410, the blocking structure 408 is adaptive to block the material of the sealing layer 410 from overflowing into the functional area 406, thus avoiding contamination of the functional area 406.

In other embodiments, the sealing layer may also be arranged on the sidewall of the blocking structure, and may also be arranged on the circuit wiring layer and on the substrate.

It should be noted that, in this embodiment, the blocking structure 408 and the solder bump 411 are separated from each other. In other embodiments, the solder bump may also be arranged in the blocking structure and extend through the blocking structure.

Referring to FIGS. 21 and 11, the subsequent process includes: cutting the substrate along the scribe line area II to form multiple individual packaging structures as shown in FIG. 11.

In the packaging method provided by the present disclosure, since a blocking structure for protecting a functional area is formed before forming the sealing layer, and the blocking structure is adaptive to block the material of the sealing layer from overflowing into the functional area, the functional area is protected from being contaminated, resulting in improved performance and yield of the formed packaging structure.

Although the present technical solution is disclosed above, it is not limited thereto. Any changes and modifications may be made by those skilled in the art without departing from the spirit and scope of the invention, and the scope of the disclosure should be determined by the scope defined by the claims.

1. A packaging structure, comprising:
a substrate;
a circuit wiring layer arranged on the substrate;
a conductive bump arranged on the circuit wiring layer;
a semiconductor chip flip-chip mounted over the substrate, wherein a functional area and a pad surrounding the functional area are arranged on a first surface of the semiconductor chip facing the substrate, and the pad is electrically connected to the conductive bump;
a sealing layer arranged on the substrate, wherein the sealing layer surrounds the semiconductor chip; and
a blocking structure arranged on the substrate, wherein the blocking structure surrounds the functional area to block a material of the sealing layer from overflowing into the functional area.

2. (canceled)

3. The packaging structure according to claim 1, wherein the conductive bump encloses a designated area, and the blocking structure is in the designated area.

4. The packaging structure according to claim 3, wherein the blocking structure is arranged between the conductive bump and the functional area, a top surface of the blocking structure is in contact with the first surface of the semiconductor chip, and a bottom surface of the blocking structure is in contact with the substrate.

5. The packaging structure according to claim 3, wherein a top surface width dimension of the blocking structure is less than or equal to a bottom surface width dimension in a direction parallel to a top surface of the substrate.

6. The packaging structure according to claim 1, wherein the conductive bump encloses a designated area, the blocking structure is outside the designated area and between the semiconductor chip and the substrate.

7. The packaging structure according to claim 6, wherein an area where the semiconductor chip is projected onto the substrate is a projection area, the blocking structure is arranged in the projection area, and a top surface of the blocking structure is in contact with the first surface of the semiconductor chip, and a bottom surface of the blocking structure is in contact with the substrate.

8. The packaging structure according to claim 6, wherein the blocking structure comprises:
a first blocking structure; and
a second blocking structure attached to one side of the first blocking structure,
wherein an area where the semiconductor chip is projected onto the substrate is a projection area, the first blocking structure is arranged outside the projection area, the second blocking structure is arranged in the projection area, and a top surface of the second blocking structure is in contact with the first surface of the semiconductor chip.

9. The packaging structure according to claim 8, wherein a thickness of the second blocking structure on the substrate is a first thickness, and a distance between the first surface of the semiconductor chip and the substrate is equal to the first thickness.

10. The packaging structure according to claim 9, wherein a thickness of the first blocking structure on the substrate is a second thickness, wherein the second thickness is greater than or equal to the first thickness.

11. The packaging structure according to claim 8, wherein the sealing layer is further arranged on a top of the first blocking structure.

12. The packaging structure according to claim 1, wherein an area where the semiconductor chip is projected onto the substrate is a projection area. The blocking structure is arranged outside the projection area, and a top of the blocking structure is higher than the first surface of the semiconductor chip.

13. The packaging structure according to claim 12, wherein there is a gap between the blocking structure and a sidewall of the semiconductor chip in a direction parallel to a top surface of the substrate.

14. The packaging structure according to claim 13, wherein a width dimension of the gap is 2 micrometers to 10 micrometers in the direction parallel to the top surface of the substrate.

15. The packaging structure according to claim 13, wherein a distance between the top surface of the blocking structure and the first surface of the semiconductor chip is 2 micrometers to 10 micrometers in a direction perpendicular to the top surface of the substrate.

16. The packaging structure according to claim 12, wherein the sealing layer is arranged on the top of the blocking structure.

17. The packaging structure according to claim 1, wherein a shape of the blocking structure is a closed loop.

18. The packaging structure according to claim 1, wherein the blocking structure is in contact with a sidewall of the conductive bump, and a material of the blocking structure is an insulating material.

19. The packaging structure according to claim 1, wherein the blocking structure and the conductive bump are separated from each other, and a material of the blocking structure is an insulating material or a conductive material.

20. (canceled)

21. The packaging structure according to claim 1, wherein the blocking structure is a stacked structure comprising:
a bottom blocking layer in contact with the substrate and the circuit wiring layer; and
a top blocking layer in contact with the first surface of the semiconductor chip,
wherein a material of the bottom blocking layer is an insulating material, and a material of the top blocking layer is a conductive material or an insulating material.

22-25. (canceled)

26. A packaging method, comprising:
providing a plurality of individual semiconductor chips, wherein a first surface of each of the plurality of the individual semiconductor chips has a functional area and a pad surrounding the functional area;
providing a substrate, wherein the substrate comprises flip-chip areas and a scribe line area between adjacent flip-chip areas;
providing a circuit wiring layer on each of the flip-chip areas of the substrate;
flip-chip mounting the semiconductor chips over the flip-chip areas of the substrate, wherein the pad and the circuit wiring layer are electrically connected by a conductive bump;
forming a sealing layer on the substrate, wherein the sealing layer surrounds each of the semiconductor chips; and
cutting the substrate along the scribe line area after forming the sealing layer, to form a plurality of individual packaging structures;
wherein before forming the sealing layer, the packaging method further comprises:
forming a blocking structure on the substrate, wherein the blocking structure surrounds the functional area to block a material of the sealing layer from overflowing into the functional area.

27-37. (canceled)
